(19) United States
(12) Patent Application Publication
(10) Pub. No.: US 2020/0132783 A1
(43) Pub. Date: Apr. 30, 2020

(54) OPPORTUNISTIC MAGNETOMETER CALIBRATION

(71) Applicant: QUALCOMM Incorporated, San Diego, CA (US)

(72) Inventors: Vivek SANKARAVADIVEL, Fremont, CA (US); William MORRISON, San Francisco, CA (US); Himanshu SHAH, Milpitas, CA (US); Songwon JEE, Sunnyvale, CA (US); Manish KUSHWAHA, San Jose, CA (US)

(21) Appl. No.: 16/664,981

(22) Filed: Oct. 28, 2019

Related U.S. Application Data
(60) Provisional application No. 62/752,826, filed on Oct. 30, 2018.

(51) Int. Cl. G01R 33/00; H04M 1/02

(52) U.S. Cl. CPC G01R 33/0035; H04M 2250/12; H04M 1/0202

(57) ABSTRACT

A mobile device includes: a magnetometer configured to sense a magnetic field and to provide indications of the magnetic field; and a processor communicatively coupled to the magnetometer and configured to: determine an occurrence of a trigger condition associated with imminent motion of the mobile device, present motion of the mobile device, or decalibration of the magnetometer; respond to determining the occurrence of the trigger condition by causing the magnetometer to sense the magnetic field and to provide the indications of the magnetic field; and determine at least one bias of the magnetometer using the indications of the magnetic field.

### CROSS-REFERENCE TO RELATED APPLICATIONS

This application claims the benefit of U.S. Provisional Application No. 62/752,826, filed Oct. 30, 2018, entitled “OPPORTUNISTIC MAGNETOMETER CALIBRATION,” the entire contents of which is hereby incorporated herein by reference.

### BACKGROUND

Mobile communication devices, for example, cellular telephones, portable navigation units, laptop computers, personal digital assistants, etc. play an important role in allowing persons in today's society to maintain mobility. For example, mobile communication devices may enable users to request or access information, services, etc. in a variety of places and at a variety of times via one or more applications hosted on computing platforms associated with these devices. Such applications may include, for example, navigation or position-tracking applications, geo-processing or mapping applications, Web-browsing applications, game or music-related applications, etc.

To support some applications, mobile communication devices may employ one or more of a variety of sensors. These sensors may typically, although not necessarily, be capable of converting physical phenomena into analog or digital signals and may be integrated into (e.g., built-in, etc.) or otherwise supported by (e.g., stand-alone, etc.) a mobile communication device. For example, a mobile communication device may feature one or more accelerometers, gyroscopes, magnetometers, gravitometers, ambient light detectors, proximity sensors, thermometers, etc., capable of measuring various motion states, locations, orientations, ambient environments, etc. of the mobile device. Sensors may be utilized individually or may be used in combination with other sensors, e.g., depending on a particular application. Multi-dimensional sensors, such as magnetometers and accelerometers, are increasingly used in mobile applications for location or orientation awareness. For example, a tilt-compensated digital compass may be used in applications such as pedestrian navigation. A tilt-compensated digital compass may include a three-dimensional magnetometer to measure the Earth's magnetic field and a three-dimensional accelerometer for tilt compensation.

Obtaining or providing useful (e.g., accurate) sensor measurements for use by applications hosted on a mobile communication device may help (facilitate, enable or even improve or enhance) performance of such applications. Further, sensors such as magnetometers may fall out of calibration, e.g., due to coming in close proximity with a strong magnet, etc. Accordingly, it may be desirable to calibrate one or more associated sensors in some manner over the life of a mobile device.

### SUMMARY

An example mobile device includes: a magnetometer configured to sense a magnetic field and to provide indications of the magnetic field; and a processor communicatively coupled to the magnetometer and configured to: determine an occurrence of a trigger condition associated with imminent motion of the mobile device, present motion of the mobile device, or decalibration of the magnetometer; respond to determining the occurrence of the trigger condition by causing the magnetometer to sense the magnetic field and to provide the indications of the magnetic field; and determine at least one bias of the magnetometer using the indications of the magnetic field.

Implementations of such a mobile device may include one or more of the following features. To determine the occurrence of the trigger condition, the processor is configured to determine that: the mobile device received an incoming phone call request; or the mobile device received an outgoing phone call request; or a phone call between the mobile device and another device is terminated; or the mobile device received an incoming message; or the mobile device sent an outgoing message; or the mobile device produced a visual notice, an audio notice, or an audiovisual notice; or a biometric sensor of the mobile device received input from a user; or the mobile device changed orientation with respect to a direction of gravity; or a magnetic cable has been detached from the mobile device; or a camera of the mobile device is activated; or the camera of the mobile device is deactivated; or facial recognition of the mobile device is activated; or a combination of two or more of these. The processor may be configured to cause the magnetometer to stop providing the indications of the magnetic field in response to a power budget for the magnetometer being reached. The processor may be configured to disable the magnetometer in response to a threshold amount of time passing after the occurrence of the trigger condition without an occurrence of another trigger condition. The processor may be configured to compensate for the at least one bias when analyzing further indications of magnetic field from the magnetometer to determine an orientation of the mobile device. The magnetometer may be configured to provide the indications of the magnetic field as indications of magnetic field intensity in each of three orthogonal directions, and the processor may be configured to determine the at least one bias as a distance bias in each of the three orthogonal directions. The processor may be configured to limit an amount of energy used to determine the at least one bias of the magnetometer. The processor may be configured to limit the amount of energy used to determine the at least one bias of the magnetometer to a threshold percentage of an amount of energy stored by a battery of the mobile device.

An example method of obtaining and processing readings of a magnetometer of a mobile device includes: determining an occurrence of a trigger condition associated with imminent motion of the mobile device, present motion of the mobile device, or decalibration of the magnetometer; causing, in response to determining the occurrence of the trigger condition, the magnetometer to sense a magnetic field and to provide indications of the magnetic field; and determining at least one bias of the magnetometer using the indications of the magnetic field.

Implementations of such a method may include one or more of the following features. Determining the occurrence of the trigger condition includes determining that: the mobile device received an incoming phone call request; or the mobile device received an outgoing phone call request; or a phone call between the mobile device and another device is terminated; or the mobile device received an incoming message; or the mobile device sent an outgoing message; or the mobile device produced a visual notice, an audio notice, or an audiovisual notice; or a biometric sensor of the mobile device received input from a user; or the mobile device changed orientation with respect to a direction of gravity; or a magnetic cable has been detached from the mobile device; or a camera of the mobile device is activated; or the camera of the mobile device is deactivated; or facial recognition of the mobile device is activated; or a combination of two or more of these. The method may include causing the magnetometer to stop providing the indications of the magnetic field in response to a power budget for the magnetometer being reached. The method may include disabling the magnetometer in response to a threshold amount of time passing after the occurrence of the trigger condition without an occurrence of another trigger condition. The method may include using the at least one bias to analyze further indications of magnetic field from the magnetometer to determine an orientation of the mobile device. The indications may include indications of magnetic field intensity in each of three orthogonal directions, and each of the at least one bias may be a respective distance bias in a respective one of the three orthogonal directions. The method may include limiting an amount of energy used to determine the at least one bias of the magnetometer, e.g., to a threshold percentage of an amount of energy stored by a battery of the mobile device.

Another example of a mobile device includes: means for sensing a magnetic field and providing indications of the magnetic field; means for determining an occurrence of a trigger condition associated with imminent motion of the mobile device, present motion of the mobile device, or decalibration of the means for sensing the magnetic field; means for causing, in response to the occurrence of the trigger condition, the means for sensing to sense the magnetic field and to provide the indications of the magnetic field; and means for determining at least one bias of the means for sensing using the indications of the magnetic field.

Implementations of such a mobile device may include one or more of the following features. The means for determining the occurrence of the trigger condition are for determining that: the mobile device received an incoming phone call request; or the mobile device received an outgoing phone call request; or a phone call between the mobile device and another device is terminated; or the mobile device received an incoming message; or the mobile device sent an outgoing message; or the mobile device produced a visual notice, an audio notice, or an audiovisual notice; or a biometric sensor of the mobile device received input from a user; or the mobile device changed orientation with respect to a direction of gravity; or a magnetic cable has been detached from the mobile device; or a camera of the mobile device is activated; or the camera of the mobile device is deactivated; or facial recognition of the mobile device is activated; or a combination of two or more of these. The mobile device may include means for causing the means for sensing to stop providing the indications of the magnetic field in response to a power budget for the means for sensing being reached. The mobile device may include means for disabling the means for sensing in response to a threshold amount of time passing after the occurrence of the trigger condition without an occurrence of another trigger condition. The mobile device may include means for analyzing further indications of magnetic field from the means for sensing to determine an orientation of the mobile device using the at least one bias. The indications may include indications of magnetic field intensity in each of three orthogonal directions, and each of the at least one bias may be a respective distance bias in a respective one of the three orthogonal directions. The means for determining the at least one bias of the means for sensing may comprise limiting means for limiting an amount of energy used to determine the at least one bias of the means for sensing. The limiting means may be for limiting the amount of energy used to determine the at least one bias of the magnetometer to a threshold percentage of an amount of energy stored by a battery of the mobile device.

An example non-transitory, processor-readable storage medium include processor-readable instructions to cause a processor to: determine an occurrence of a trigger condition associated with imminent motion of a mobile device, present motion of the mobile device, or decalibration of a magnetometer of the mobile device; cause, in response to determining the occurrence of the trigger condition, the magnetometer to sense a magnetic field and to provide indications of the magnetic field; and determine at least one bias of the magnetometer using the indications of the magnetic field.

Implementations of such a storage medium may include one or more of the following features. The instructions to cause the processor to determine the occurrence of the trigger condition comprise instructions to cause the processor to determine that: the mobile device received an incoming phone call request; or the mobile device received an outgoing phone call request; or a phone call between the mobile device and another device is terminated; or the mobile device received an incoming message; or the mobile device sent an outgoing message; or the mobile device produced a visual notice, an audio notice, or an audiovisual notice; or a biometric sensor of the mobile device received input from a user; or the mobile device changed orientation with respect to a direction of gravity; or a magnetic cable has been detached from the mobile device; or a camera of the mobile device is activated; or the camera of the mobile device is deactivated; or facial recognition of the mobile device is activated; or a combination of two or more of these. The storage medium may include instructions to cause the magnetometer to stop providing the indications of the magnetic field in response to a power budget for the magnetometer being reached. The storage medium may include instructions to disable the magnetometer in response to a threshold amount of time passing after the occurrence of the trigger condition without an occurrence of another trigger condition. The storage medium may include instructions to determine an orientation of the mobile device using the at least one bias and further indications of magnetic field from the magnetometer. The indications may include indications of magnetic field intensity in each of three orthogonal directions, and each of the at least one bias may be a respective distance bias in a respective one of the three orthogonal directions. The storage medium may include instructions configured to cause the processor to limit an amount of energy used to determine the at least one bias of the magnetometer, e.g., to a threshold percentage of an amount of energy stored by a battery of the mobile device.

### BRIEF DESCRIPTION OF THE DRAWINGS

FIG. 1 is a schematic diagram of a navigation system.

FIG. 2 is a block diagram of components of an example of a mobile device shown in FIG. 1.

FIG. 3 is a block diagram of components of another example of a mobile device shown in FIG. 1.

FIG. 4 is a perspective view of a three-dimensional magnetometer shown in FIG. 2 or FIG. 3.

FIG. 5 is a perspective view of a unit circle and unit sphere, centered on an origin, of measurements from a calibrated two-dimensional magnetometer and three-dimensional magnetometer, respectively, of a mobile device shown in FIG. 1.

FIG. 6 is a perspective view of an ellipse and an ellipsoid, offset from an origin, of measurements from an out-of-calibration two-dimensional magnetometer and an out-of-calibration three-dimensional magnetometer, respectively, of a mobile device shown in FIG. 1.

FIG. 7 is a block flow diagram of a method of obtaining and processing readings of a magnetometer of a mobile device shown in FIG. 1.

### DETAILED DESCRIPTION

Techniques are discussed herein for opportunistically calibrating a magnetometer. For example, techniques are discussed for opportunistically obtaining magnetometer measurements and using the measurements to calibrate the magnetometer. A magnetometer may be placed in an idle (e.g., off) mode when the magnetometer is not moving, which may reduce power consumption by the magnetometer and avoid power consumption for worthless measurements when the magnetometer is not moving. The magnetometer may be actuated to trigger measurement by the magnetometer in response to occurrence of a condition associated with the magnetometer being moved, or likely being moved. Other configurations, however, may be used.

Items and/or techniques described herein may provide one or more of the following capabilities, as well as other capabilities not mentioned. Magnetometer power consumption may be reduced. Power consumption for magnetometer measurements while a magnetometer is stationary may be reduced. Magnetometer calibration may be performed before magnetometer readings are requested such that delay in useful magnetometer output and/or information derived from magnetometer output is quickly available when requested, e.g., without having to wait for magnetometer calibration. It may be possible for an effect noted above to be achieved by means other than that noted, and a noted item/technique may not necessarily yield the noted effect.

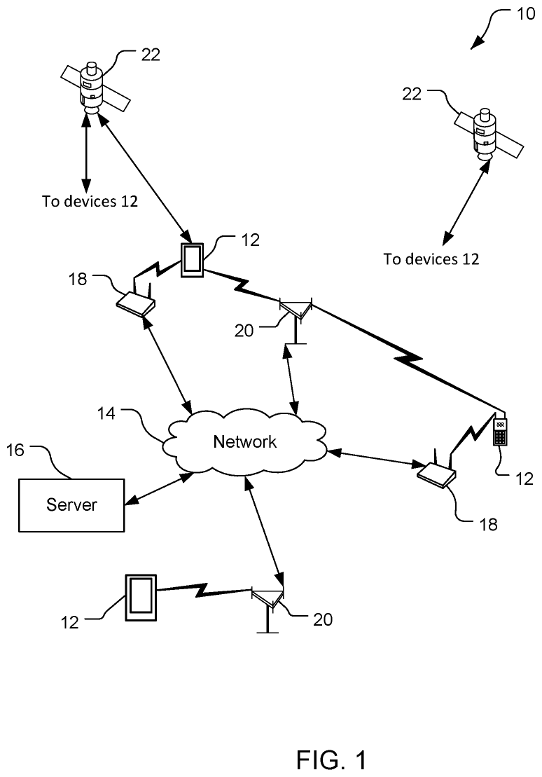

Referring to FIG. 1, a communication and navigation system 10 includes mobile devices 12, a network 14, a server 16, access points (APs) 18, base transceiver stations (BTSs) 20, and satellites 22. The system 10 is a wireless communication system in that components of the system 10 can communicate with one another (at least some times using wireless connections) directly or indirectly, e.g., via the network 14 and/or one or more of the access points 18 and/or one or more of the base transceiver stations 20 (and/or one or more other devices not shown). For indirect communications, the communications may be altered during transmission from one entity to another, e.g., to alter header information of data packets, to change format, etc. The mobile devices 12 shown are mobile wireless communication devices (although they may communicate wirelessly and via wired connections) including mobile phones (including smartphones) and a tablet computer. Other mobile devices 12 may include wearable devices (e.g., smart watches, smart jewelry, smart glasses or headsets, etc.). Still other mobile devices may be used, whether currently existing or developed in the future. Further, other wireless devices (whether mobile or not) may be implemented within the system 10 and may communicate with each other and/or with the mobile devices 12, network 14, server 16, the APs 18, and/or the BTSs 20. For example, such other devices may include internet of thing (IoT) devices, medical devices, home entertainment and/or automation devices, etc.

The mobile devices 12 or other devices may be configured to communicate in different networks and/or for different purposes (e.g., 5G, Wi-Fi communication, multiple frequencies of Wi-Fi communication, satellite positioning, one or more types of cellular communications (e.g., GSM (Global System for Mobiles), CDMA (Code Division Multiple Access), LTE (Long-Term Evolution), etc.). The system 10 may support operation on multiple carriers (waveform signals of different frequencies). Multi-carrier transmitters can transmit modulated signals simultaneously on the multiple carriers. Each modulated signal may be a Code Division Multiple Access (CDMA) signal, a Time Division Multiple Access (TDMA) signal, an Orthogonal Frequency Division Multiple Access (OFDMA) signal, a Single-Carrier Frequency Division Multiple Access (SC-FDMA) signal, etc. Each modulated signal may be sent on a different carrier and may carry pilot, overhead information, data, etc.

The BTSs 20 may wirelessly communicate with the mobile devices 12 in the system 10 via antennas. A BTS 20 may also be referred to as a base station, an access point, an access node (AN), a Node B, an evolved Node B (eNB), etc. The BTSs 20 may configured to communicate with mobile devices 12 via multiple carriers. The BTSs 20 may provide communication coverage for a respective geographic area, e.g. a cell. Each cell may be partitioned into multiple sectors as a function of the base station antennas.

The system 10 may include only macro BTSs 20 or the system 10 may have BTSs 20 of different types, e.g., macro, pico, and/or femto base stations, etc. A macro base station may cover a relatively large geographic area (e.g., several kilometers in radius) and may allow unrestricted access by terminals with service subscription. A pico base station may cover a relatively small geographic area (e.g., a pico cell) and may allow unrestricted access by terminals with service subscription. A femto or home base station may cover a relatively small geographic area (e.g., a femto cell) and may allow restricted access by terminals having association with the femto cell (e.g., terminals for users in a home).

The mobile devices 12 may be referred to as terminals, access terminals (ATs), mobile stations, user equipment (UE), subscriber units, etc. The mobile devices 12 can include various devices as listed above and/or other devices.

The system 10 is also a navigation system. The mobile devices 12 may use signals from the BTSs 20 and/or the satellites 22 to determine navigation-related information such as position, velocity, speed, heading, etc. One or more of the mobile devices 12 may also include sensors for use in determining navigation-related information. Sensor information may yield the navigation information directly, or may be used to derive the navigation information. As shown in FIG. 1, the mobile devices 12 may receive navigation signals from a satellite positioning system (SPS), e.g., through the satellites 22. The satellites 22 may be associated with a single navigation system such as a global navigation satellite system (GNSS) or multiple navigation systems. Examples of possible navigation systems associated with the satellites 22 may include, but are not limited to, Global Positioning System (GPS), Galileo, Glonass, Beidou (Compass), etc. The satellites 22 may be referred to as SPS satellites, space vehicles (SVs), etc.

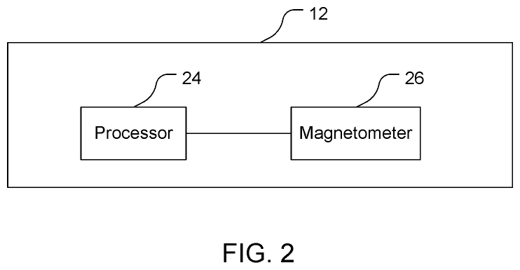

Referring also to FIG. 2, an example of one of the mobile devices 12 comprises a computing platform including a processor 24 and a magnetometer 26. The processor 24 and the magnetometer 26 may be communicatively coupled to each other (e.g., to provide electrical and/or optical signals to each other). The processor 24 may be an intelligent hardware device, e.g., a central processing unit (CPU) such as those made by QUALCOMM®, ARM®, Intel® Corporation, or AMD®, a microcontroller, an application specific integrated circuit (ASIC), etc. The processor 24 could comprise multiple separate physical entities that can be distributed in the mobile device 12. The processor 24 may include a memory, e.g., a non-transitory storage medium that stores processor-readable, processor-executable software code containing instructions that are configured to, when executed, cause the processor 24 to perform various functions described herein. Alternatively, the software may not be directly executable by the processor 24 but may be configured to cause the processor 24, e.g., when compiled and executed, to perform the functions. The magnetometer 26 may be configured to sense a magnetic field and to provide indications of the magnetic field. The indications may be, for example, electrical and/or optical signals transmitted from the magnetometer 26 to the processor 24. The indications may include raw information indicative of measurements made by the magnetometer 26, for example, indicating a magnitude (e.g., magnetic field intensity, e.g., in two or three orthogonal directions) and/or direction of a magnetic field sensed by the magnetometer 26. The indications may include processed data, e.g., processed measurement data indicative of an orientation of the mobile device 12.

The processor 24 may be configured to determine biases of the magnetometer. The processor 24 may be configured to determine an occurrence of a trigger condition associated with imminent motion of the mobile device 12, present motion of the mobile device 12, or decalibration of the magnetometer 26. The processor 24 may be configured to respond to determining the occurrence of the trigger condition by causing the magnetometer 26 to sense the magnetic field and to provide the indications of the magnetic field. The processor 24 may further be configured to determine the biases of the magnetometer using the indications of the magnetic field as discussed more fully herein.

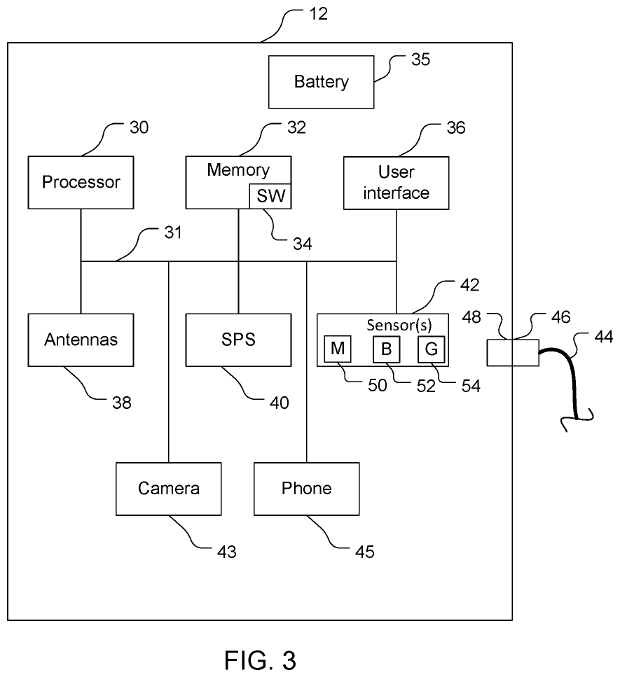

Referring also to FIG. 3, another example of one of the mobile devices 12 comprises a computing platform including a processor 30, memory 32 including software 34, a battery 35, a user interface 36, antennas 38, a satellite positioning system (SPS) module 40, here a Global Positioning System (GPS) module, sensors 42, a camera 43, and a phone module 45. The processor 30, the memory 32, the user interface 36, the antennas 38, the SPS module 40, the sensors 42, the camera 43, and the phone module 45 may be communicatively coupled to each other by a bus 31 (that may be configured to convey, e.g., electrical and/or optical signals between the processor 30, the memory 32, the user interface 36, the antennas 38, the SPS module 40, the sensor(s) 42, the camera 43, and/or the phone module 45). The battery 35 may be connected to provide energy to any component of the mobile device 12, e.g., the processor 30, the memory 32, the user interface 36, the SPS module 40, the sensor(s) 42, the camera 43, and the phone module 45. The processor 30 may be coupled to the battery 35 and configured to monitor an energy level of the battery 35, e.g., an amount of energy stored by the battery 35. The antennas 38 may include a transceiver configured to communicate bi-directionally with the BTSs 20 and the access points 18 via the antennas 38. The processor 30 may be an intelligent hardware device, e.g., a central processing unit (CPU) such as those made by QUALCOMM®, ARM®, Intel® Corporation, or AMD®, a microcontroller, an application specific integrated circuit (ASIC), etc. The processor 30 could comprise multiple separate physical entities that can be distributed in the mobile device 12. The memory 32 is a non-transitory storage medium that may include random access memory (RAM) and read-only memory (ROM). The memory 32 stores the software 34 which may be processor-readable, processor-executable software code containing instructions that are configured to, when executed, cause the processor 30 to perform various functions described herein. Alternatively, the software 34 may not be directly executable by the processor 30 but may be configured to cause the processor 30, e.g., when compiled and executed, to perform the functions. The user interface 36 may include one or more devices for providing information to, and/or receiving information from, a user. For example, the user interface 36 may include a touch-sensitive screen, a microphone, and/or a speaker, etc. The camera 43 is configured to capture images (e.g., still images and/or video images) and provide the captured images to the memory 32 and/or the processor 30. The phone module 45 is configured (e.g., includes an appropriately configured transceiver) to coordinate phone calls according to one or more protocols, e.g., 3G, 4G, 4G LTE, etc. The phone module 45 may be configured to work with the processor 30, one or more of the antennas 38, and the user interface 36 to initiate outgoing calls, receive incoming calls, process ongoing calls, and terminate calls. The phone module 45 may provide information regarding calls (e.g., indicating that an incoming call is being requested or that an outgoing call is being requested/initiated) to the processor 30.

The SPS module 40 may include appropriate equipment for monitoring SPS signals from the satellites 22 and for determining navigation information (e.g., position, velocity, etc.) of the mobile device 12. For example, the SPS module 40 includes one or more SPS antennas, and may either communicate with the processor 30 to determine location information or may use its own processor for processing the received SPS signals to determine the navigation information for the mobile device 12. Further, the SPS module 40 may communicate with other entities such as a position-determination entity and/or one or more of the BTSs 20 in order to send and/or receive assistance information for use in determining the navigation information for the mobile device 12.

The sensors 42 may include one or more orientation sensors and/or one or more other sensors. For example, the sensors 42 may include a magnetometer 50, a biometric sensor 52, a gyroscope 54, and/or an accelerometer (not shown), and/or one or more other sensors. In this example, three sensors are included in the mobile device 12, but this is not required and other quantities of sensors (e.g., one, two, etc.) may be included in the mobile device 12. The sensors 42 may include a sensor for detecting that a cable 44 (e.g., specifically a plug 46 of the cable 44) has been disconnected (e.g., detached) from a port 48 of the mobile device 12. For example, the cable 44 may include a magnet to help the cable 44 initially connect to, and/or to stay connected to, the port 48. This magnet may de-calibrate the magnetometer 50 of the sensors 42 or may otherwise affect the signals generated by the magnetometer 50 such as by introducing a bias into the magnetometer 50 and/or signals provided by the magnetometer 50. The sensor for detecting disconnection of the cable 44 from the port 48 may, however, be part of the processor 30 and/or the memory 32 (specifically the software 34), e.g., for detecting termination of charging of the mobile device 12, etc. The magnetometer 50 may be a two-dimensional magnetometer configured to detect and provide indications of magnetic field strength in two orthogonal dimensions. Alternatively, the magnetometer 50 may be a three-dimensional magnetometer configured to detect and provide indications of magnetic field strength in three orthogonal dimensions. The biometric sensor 52 may be, for example, a fingerprint sensor or scanner configured to scan a finger of a user of the mobile device 12, e.g., for authentication and/or authorization purposes. The gyroscope can provide information indicative of a change in orientation of the mobile device 12, e.g., relative to a direction of gravity. The information from the gyroscope may itself indicate the change in orientation or the information may be processed by the processor 30 to determine a change in orientation of the mobile device. Still other configurations of magnetometers may be used.

The magnetometer 50 may determine magnetic field strengths in different directions which may be used to determine orientation of the mobile device 12. For example, the orientation may be used to provide a digital compass for the mobile device, e.g., that may be used to show a user, through a display of the user interface 36, and heading of the mobile device 12. The magnetometer 50 may provide means for sensing a magnetic field and providing indications of the magnetic field, e.g., to the processor 30. The processor 30, e.g., in combination with the software 34 and possibly in combination with the magnetometer 50, may provide means for analyzing indications of magnetic field (e.g., with calibration factors applied, e.g., by the magnetometer 50 or the processor 30, to raw magnetic field data to yield the indications) to determine the orientation of the mobile device 12.

In order for the magnetometer 50 to provide useful information for accurately determining the orientation of the mobile device 12, the magnetometer 50 may be calibrated to remove biases that may occur. The biases, for example, may be induced by a strong magnetic field being applied to the mobile device 12, e.g., by having a magnet disposed in close proximity to the mobile device 12. Biases of the magnetometer 50 may result due to the passage of time such that the sensors gradually get out of calibration even without having a strong magnetic field applied to the magnetometer. The biases are different from device to device especially due to environmental influences that are specific to devices. Thus, it may be desirable to calibrate the magnetometer 50 of each mobile device 12. The processor 30 may be configured to compensate for one or more biases of the magnetometer 50 to help calibrate the magnetometer 50.

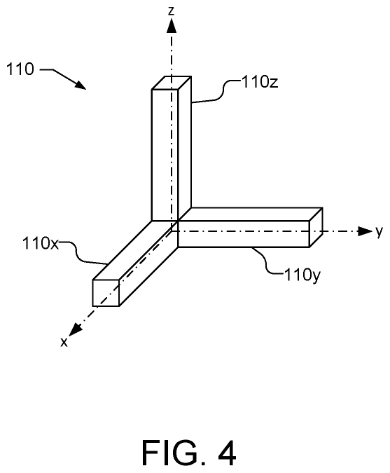

Referring also to FIG. 4, an example of the magnetometer 50 is a multi-dimensional sensor 110. The multi-dimensional sensor 110 is a three-dimensional sensor that includes a sensor 110x along an x-axis, a sensor 110y along a y-axis, and a sensor 110z along a z-axis. The multi-dimensional sensor 110 may, however, be a two-dimensional sensor including only the sensor 110x and the sensor 110y, along the x-axis and y-axis, respectively. The multi-dimensional sensor 110 provides raw, uncalibrated data for each axis from a respective one of the sensors 110x, 110y, 110z. The raw data may be used, e.g., by the processor 30, to determine an initial, uncompensated orientation of the mobile device 12. More than one multi-dimensional sensor may be used as well, for instance, a three-dimensional accelerometer and a magnetometer may be used as a digital compass.

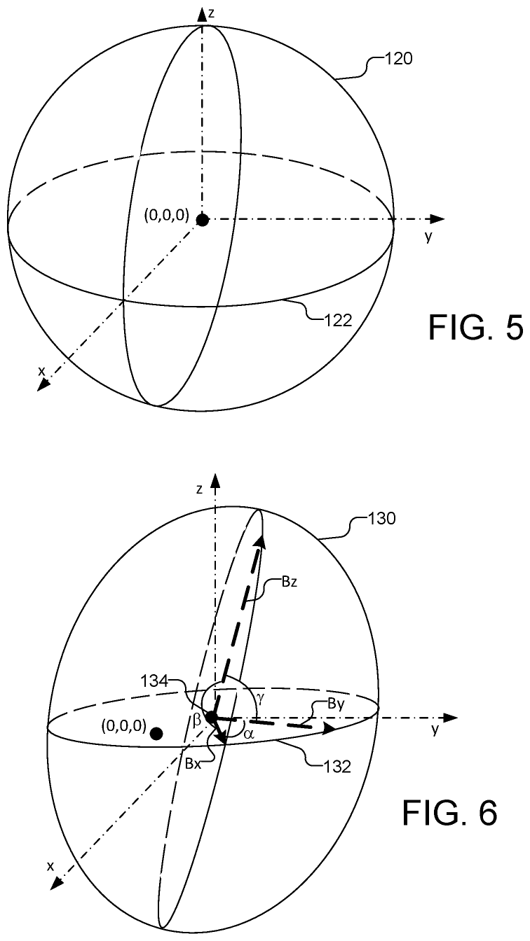

Referring also to FIGS. 5 and 6, the raw data output by the multi-dimensional sensor may be plotted to form a three-dimensional shape. The raw data output from the multi-dimensional sensor 110 captured at numerous orientations would ideally yield a unit sphere 120 (FIG. 5) centered on an origin, i.e., (0,0,0) of the x-y-z coordinate system indicated by the x-axis, the y-axis, and the z-axis. The raw data would ideally yield a unit circle 122 centered on the origin, i.e., (0,0) in the case of a two-dimensional sensor. In practice, however, several error or sources affect the multi-dimensional sensor 110 resulting in an output that is an ellipsoid 130 (FIG. 6) that is offset from the origin (or an ellipse 132 in the case of a two-dimensional sensor). The shapes of the ellipsoid 130 and the ellipse 132 shown in FIG. 6 are examples only, and different shapes would result from different errors. Error sources for the multi-dimensional sensor 110 include a DC offset along each axis of the multi-dimensional sensor 110, differing sensitivities of the sensors 110x, 110y, and 110z (if used), and non-orthogonality between different pairs of the sensors 110x, 110y, and 110z (if used).

DC offset error is a non-zero bias in the sensors 110x, 110y, 110z that results in a shift in the values of the outputs of the sensors 110x, 110y, 110z. The DC offset error may differ for each of the sensors 110x, 110y, 110z. Hard-iron errors in the sensor 110, being a magnetometer, may be included in the DC offset error. A hard-iron error may be caused by the multi-dimensional sensor 110 detecting a constant magnetic field in addition to the Earth's magnetic field. If the source of the hard-iron error has a fixed positional relationship with respect to the multi-dimensional sensor 110, resulting in a constant shift in the values of the outputs of the sensors 110x, 110y, 110z, then the hard-iron errors may be included in the DC offset error. FIG. 6 illustrates the DC offset error as an offset of the ellipsoid 130 or ellipse 132 from the origin (0,0,0) to a point 134.

Sensitivity error is an error source that results from differing sensitivities of the sensors 110x, 110y, 110z with respect to each other. The sensitivity of a sensor along an axis scales the value of the output of that sensor. One sensor, e.g., the sensor 110x, may be more sensitive than another sensor, e.g., the sensor 110y, and thus the values of the outputs of the sensors 110x, 110y are scaled differently. Additionally, soft-iron errors in the sensor 110, being a magnetometer, may be included in the sensitivity error. A soft-iron error is caused by materials that emit a variable magnetic field near the multi-dimensional sensor 110. If the source of the soft-iron error has a fixed positional relationship with respect to the multi-dimensional sensor 110, resulting in consistent but unequal scaling of the values of the outputs of the sensors 110x, 110y, 110z, then the soft-iron errors may be included in the sensitivity error. FIG. 6 illustrates the sensitivity error of the sensors 110x, 110y, 110z with differing lengths of vectors labeled Bx, By, Bz, respectively. Calibration of sensitivity differences may be performed during manufacture and thus the scaling differences of the sensors 110x, 110y, 110z may be accounted for during manufacture. These differences are constant or nearly so such that calibration during use of the mobile device 12 need not determine calibration factors to compensate for different sensitivities.

Non-orthogonality error results from the sensors 110x, 110y, 110z being physically misaligned with the x-axis, y-axis, and z-axis, respectively. As illustrated in FIG. 6, there exists an angle α between the vectors Bx and By, an angle β between the vectors Bx and Bz, and an angle γ between the vectors By and Bz. A non-orthogonality error ψ between the vectors Bx and By is 0.5*(90°−α), a non-orthogonality error θ between the vectors Bx and Bz is 0.5*(90°−β) and a non-orthogonality error ϕ between the vectors By and Bz is 0.5*(90°−γ). If the multi-dimensional sensor 110 is a two-dimensional sensor, the non-orthogonality error is only a single angle between the two dimensions, e.g., between the vectors Bx and By. Calibration of non-orthogonality differences may be performed during manufacture and thus the non-orthogonality differences of the sensors 110x, 110y, 110z may be accounted for during manufacture. These differences are constant or nearly so such that calibration during use of the mobile device 12 need not determine calibration factors to compensate for non-orthogonality error.

Without compensation for the error sources, processing of the raw data from the multi-dimensional sensor 110 may result in an inaccurate measurement. Calibration, i.e., determination of corrections (or compensations) for the raw data to map the ellipsoid to a sphere, may be performed using the raw data provided by the multi-dimensional sensor 110, e.g., while the sensor 110 is in use. For example, the processor 30, e.g., in combination with the software 34 and the magnetometer 50, may provide means for determining biases of means for sensing a magnetic field (e.g., the magnetometer 50) using indications of magnetic field from the means for sensing. The biases may be used for calibration of the magnetometer 50. The calibration may determine the ellipse 132 (for a two-dimensional sensor or for planes of a three-dimensional sensor) or the ellipsoid 130 (for the three-dimensional sensor) parameters and determine calibration factors to map the ellipse or ellipsoid to a circle or sphere, respectively. The calibration factors may be applied to future raw data to produce a compensated indication of magnetic field that is an accurate indication of a direction, relative to the mobile device 12, of a magnetic field in which the mobile device 12 is disposed. The indication may be a value of magnetic field intensity for each direction for which there is a sensor in the multi-dimensional sensor 110. The sensor 110 may include a processor or other processing circuit configured to process the raw data, including applying the calibration factors to the raw data, into the indication of the magnetic field. Alternatively, some or all of this processing may be performed by the processor 30 having been provided the raw data from the magnetometer 50 (here, the multi-dimensional sensor 110). The magnetometer 50, or the processor 30, may further provide an indication of a direction and/or orientation of the mobile device 12 relative to the Earth based on the compensated indication of magnetic field and a known direction of Earth's magnetic field at the location of the mobile device 12.

Calibration takes power and time, and a user may not wish to wait for the calibration when the information from the magnetometer 50 is requested. Thus, it may be desired to calibrate the magnetometer 50 before magnetometer-sensed information is requested, and on an on-going basis, such that the calibration is up to date when the magnetometer-sensed information is requested. Due, however, to the power used to calibrate the magnetometer, and typically the limited amount of power desired to be used to calibrate the magnetometer 50, it may be desirable to calibrate the magnetometer 50 intermittently to save power. For example, there may be a power budget for calibration and the processor 30 may control calibration by the magnetometer 50 to balance competing interests of (to regulate a trade-off between) accurate magnetometer data being available on demand and the limited power budget for calibrating the magnetometer 50. For example, this power budget may be a threshold amount of power or energy that is allocated for each calibration (e.g., for determining one or more biases of the magnetometer 50). The power budget may vary over time, e.g., as an amount of stored energy in the battery 35 changes (with the power budget decreasing as the amount of stored energy decreases). For example, the processor 30 may be configured to limit an amount of energy used to determine one or more magnetometer biases to a threshold percentage, such as 10% or 5%, of energy stored by the battery 35 as of when the processor 30 begins to determine the bias(es). As another example, the processor 30 may be configured to limit the amount of energy spent determining the bias(es) of the magnetometer to (1) a fixed energy amount if the battery 35 stores at least a threshold storage amount of energy (e.g., 50% of maximum energy storage) as of when the processor 30 begins to determine the bias(es), or (2) a threshold percentage of energy stored as of when the processor 30 begins determining the bias(es) if the battery 35 stores less than the threshold storage amount of energy (e.g., 50% of maximum energy storage) as of when the processor 30 begins to determine the bias(es). As another example, the power budget may be an amount of power per duration of time that may be used for calibration (e.g., a maximum amount of power per hour that may be used to calibrate the magnetometer 50). The processor 30 may control the magnetometer 50 to stop sensing the magnetic field and/or to stop providing indications of magnetic field in response to the power budget being reached. Thus, the processor 30, e.g., in combination with the software 34, may provide means for causing means for sensing a magnetic field to stop providing indications of magnetic field, e.g., in response to a power budget for the means for sensing being reached.

The processor 30 may be configured to regulate the calibration of the magnetometer 50. For example, the processor 30 may control the magnetometer 50 to shut down during times that the mobile device 12 is stationary or otherwise unlikely to be moved to different orientations, and thus during times that are unlikely to yield multiple data points for determining the calibration factors. The processor, e.g., in combination with the software 34, may provide means for disabling means for sensing a magnetic field in response to a threshold amount of time passing after the occurrence of a trigger condition without an occurrence of another trigger condition (e.g., occurrence of the same trigger condition again or occurrence of a different trigger condition). The processor 30 may be configured to actuate the magnetometer 50 (e.g., wake up the magnetometer 50) opportunistically to obtain raw magnetometer measurements (i.e., raw data from the magnetometer 50) at times that are likely to yield multiple measurements at different orientations to thus facilitate populating points on a shape (e.g., an ellipsoid or ellipse) from which calibration factors may be determined. Thus, the processor 30 (e.g., in conjunction with the software 34) may provide means for causing, in response to occurrence of a trigger condition, the magnetometer 50 (or other means for sensing a magnetic field) to sense a magnetic field and to provide indications of the magnetic field.

The processor 30 may be configured to actuate the magnetometer 50 to obtain raw magnetometer measurements in response to one or more of various trigger conditions occurring. The trigger conditions may be associated with the mobile device 12 being moved, e.g., by a user of the mobile device, and/or associated with imminent movement of the mobile device 12, and/or decalibration of the magnetometer 50. In this way, the magnetometer 50 may be actuated (from an OFF state or other state, e.g., a low-power state) to an ON state to take measurements, for use in calibration of the magnetometer 50, when the mobile device 12 is moving and/or when it is likely that the mobile device 12 will soon be in motion such that the magnetometer measurements will be taken at different orientations of the mobile device 12 as opposed to a single orientation, which helps compile a set of measurements sufficient for determining magnetometer biases and thus calibration factors. A set of measurements may be considered sufficient if, for example, a threshold quantity of measurements have been taken, or at least one measurement has been taken in a threshold number of regions a unit sphere or circle (e.g., at least one measurement in each of 60 equal-sized segments of the unit sphere 120). For example, when a phone call is received, a phone is often moved to the user's ear, and when a phone call is terminated a phone is often moved from a user's ear (e.g., to a table, a pocket, a purse, etc.). As other examples, when a camera is activated, a phone is typically moved to have the camera point in a direction to capture a desired image. Automated activation of the magnetometer 50 in response to a trigger condition for calibration measurements may avoid prompting a user of the mobile device 12 to move the mobile device 12 in order to be able to capture sufficient magnetometer measurements for calibration. Further, this automated capturing of magnetometer measurements for calibration helps avoid wasted measurements, and thus may improve efficiency of power use for calibrating the magnetometer 50, i.e., obtaining magnetometer measurements and determining calibration factors. For associations with imminent movement or decalibration, the associations may be of substantial likelihoods of imminent movement or decalibration. What is considered a substantial likelihood may be subjective and may be different for different applications. For example, which trigger condition(s) is(are) used may vary, e.g., may depend on a designer's preferences, a power budget, likelihood of movement associated with the condition, and/or one or more other factors. The processor 30, e.g., in combination with the software 34 and possibly in combination with one or more of the SPS module 40, one or more of the sensors, the camera 43, or the phone module 45 may provide means for determining occurrence of a trigger condition. Still other devices may be part of the means for determining occurrence of a trigger condition, e.g., for other examples of trigger conditions in addition to those discussed herein. The following are examples of trigger conditions in response to which the processor 30 may actuate the magnetometer 50.
1. The mobile device 12 receives an incoming phone call request. For example, the mobile device receives an incoming phone call from one of the BTSs 20.
2. The mobile device 12 sends an outgoing phone call request. For example, a user initiates a phone call by dialing a phone number or selecting an icon to place a phone call.
3. A phone call between the mobile device 12 and another device is terminated. For example, the processor 30 detects that the user of the mobile device 12 selects a hang-up or terminate icon on a display of the user interface 36, or a termination indication is received from the BTS 20 with which the mobile device 12 is communicating for the phone call.
4. The mobile device 12 receives an incoming message (e.g., a text message such as a Short Messaging Service (SMS) protocol message, an incoming social media message (e.g., a social-media post)). For example, a text message is received via one of the antennas 38 from one of the BTSs 20 or one of the Aps 18.
5. The mobile device 12 sends an outgoing message (e.g., a text message).
6. The mobile device 12 produces a visual notice, an audio notice, or an audiovisual notice. For example, the user interface 36 displays a message or an icon, and/or plays an audible sound (e.g., a ringtone, etc.). The notice could be for any of a variety of purposes, e.g., an alarm, receipt of a social-media post, a calendar reminder, etc.
7. The biometric sensor 52 receives input from a user. For example, the user of the mobile device 12 places a finger on the biometric sensor 52.
8. A change in orientation relative to gravity. For example, a gyroscope of the sensors 42 may detect a change in relationship between the mobile device 12 and gravity. The trigger condition may be that the change in orientation exceeds a threshold tilt angle.
9. Detachment of a magnetic cable from the mobile device 12. For example, the processor 30 may determine that charging of the mobile device 12 has ceased, or otherwise determine that the cable 44 has been disconnected from the port 48. This may correspond to the magnetometer 50 having been previously decalibrated. The processor 30 may actuate the magnetometer 50 to obtain calibration measurements in response to the cable 44 being disconnected because a magnet in the cable 44 may affect the magnetic field sensed by the magnetometer 50. Thus, the calibration factors with and without the cable 44 connected to the mobile device 12 may be different.
10. Activation of the camera 43.
11. Deactivation of the camera 43.
12. Facial recognition is activated. For example, a user may activate facial recognition (e.g., by the processor 30 analyzing one or more images captured by the camera 43) via the user interface 36.
   These trigger conditions are examples only and one or more other trigger conditions may be used.

The trigger condition(s) may be determined by the processor 30 and/or one or more other components in the mobile device 12. Trigger conditions may be combined such that the magnetometer 50 may be actuated to obtain raw measurement data for use in calibration in response to a combination of trigger conditions occurring. This may be considered to be a single, compound trigger condition instead of a combination of multiple trigger conditions.

The measurements taken by the magnetometer 50 in response to a trigger condition may be limited. For example, the processor 30 may deactivate the magnetometer 50 after a threshold amount of time (e.g., 10 seconds) has passed since the magnetometer was actuated in response to a trigger condition. The processor 30 may start a timer in response to actuating the magnetometer 50 in response to occurrence of a trigger condition and may deactivate the magnetometer if the timer expires. Deactivation may turn the magnetometer 50 off, or may place the magnetometer in an idle, low-power state but not fully powered off. The processor 30 may deactivate the magnetometer 50 after the threshold amount of time has passed only if no further trigger condition occurs before the threshold amount of time has passed. For example, the processor 30 may reset the timer in response to another trigger condition occurring before expiration of the timer. The threshold amount of time may vary depending upon which trigger condition occurs. As another example, the processor 30 may deactivate the magnetometer 50 after a threshold number of measurements are taken. The processor 30 may be configured to deactivate the magnetometer even if a trigger condition has occurred more recently than the threshold amount of time or before the threshold number of measurements, e.g., if sufficient measurements have been taken to determine the calibration factors and/or if the power budget has been reached.

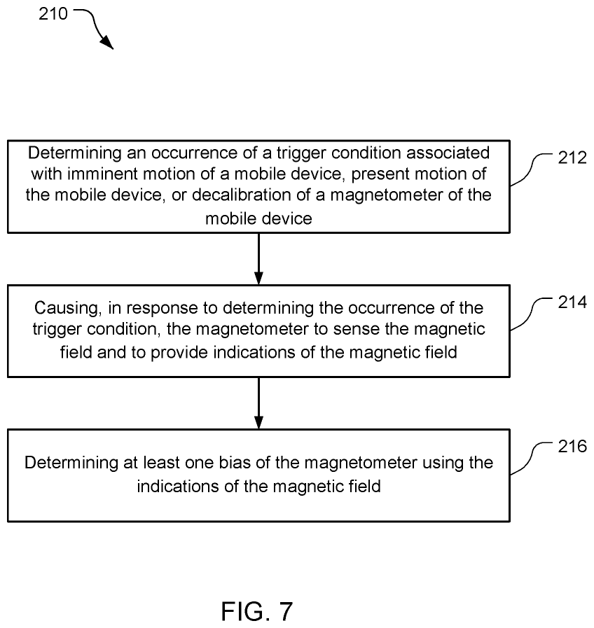

Referring to FIG. 7, with further reference to FIGS. 1-6, a method 210 of obtaining and processing readings of a magnetometer of a mobile device includes the stages shown. The method 210 is, however, an example only and not limiting. The method 210 may be altered, e.g., by having stages added, removed, rearranged, combined, performed concurrently, and/or having single stages split into multiple stages.

At stage 212, the method 210 includes determining an occurrence of a trigger condition associated with imminent motion of the mobile device, present motion of the mobile device, or decalibration of a magnetometer of the mobile device. For example, the processor 30 may determine, e.g., from data received from one or more of the sensors 42, that a trigger condition has occurred. For example, the processor 30 may determine that an incoming or outgoing phone call is being requested, that a phone call is terminated, that message is received by or sent by the mobile device 12, that a notice is provided (e.g., through the user interface 36), that the biometric sensor 52 received input, that the mobile device 12 changed orientation relative to gravity (e.g., based on information from the gyroscope 54), that a magnetic cable has been detached from the mobile device 12, that the camera 43 has been activated or deactivated, that facial recognition has been activated, or a combination of two or more of these conditions. For example, the processor 30 may determine that the trigger condition has occurred if the processor 30 determines that a message is received by the mobile device 12 and that the biometric sensor 52 received input.

At stage 214, the method 210 includes causing, in response to determining the occurrence of the trigger condition, the magnetometer to sense the magnetic field and to provide the indications of the magnetic field. For example, the processor 30 may cause the magnetometer 50 to turn from an OFF state or a low-power (e.g., sleep) state to an ON state during which the magnetometer 50 takes magnetic field measurements and provides indications of the measurements to the processor 30. The indications may be raw measurement data and/or may be processed data, e.g., indicative of an orientation of the mobile device 12. For example, the magnetometer 50 may provide indications of magnetic field intensity in multiple (e.g., two or three) orthogonal directions.

At stage 216, the method 210 includes determining at least one bias of the magnetometer using the indications of the magnetic field. For example, the processor 30 may use the indications of magnetic field measurements to determine one or more biases, e.g., biases of orthogonal magnetic field sensors. The indications may be stored, e.g., in the memory 32, for use by the processor 30 in determining the bias(es). The processor 30 may determine, based on the indications of the magnetic field, an offset of an origin of an actual sphere of measurements relative to an ideal origin of a sphere of measurements, with the offset corresponding to the bias(es). The at least one bias may be respective distance biases in respective orthogonal directions (e.g., two or three orthogonal directions). The processor 30 may further determine calibration factors, corresponding to the at least one bias, that map an ellipse or ellipsoid measured by the magnetometer 50 to a circle or sphere, respectively, and use the calibration factors to adjust measured data (present or future) for determining orientation of the mobile device, e.g., relative to the Earth's magnetic field. By determining the offset and/or the calibration factor(s), the processor 30 determines the at least one bias.

The method 210 may further include one or more of the following features. For example, the method 210 may further comprise causing the magnetometer to stop providing the indications of the magnetic field in response to a power budget for the magnetometer 50 being reached. For example, the processor 30 may determine that the power budget for the magnetometer 50 has been exhausted and, in response to this determination, cause the magnetometer to shut off (change from an ON state to an OFF state) or change from an ON state to a low-power state in which the magnetometer does not take magnetic field measurements. As another example, the method 210 may include disabling the magnetometer in response to a threshold amount of time passing after the occurrence of the trigger condition without an occurrence of another trigger condition. For example, in response to the processor 30 determining that no further trigger condition occurs for a threshold time after a trigger condition occurred in response to which the processor 30 actuated the magnetometer 50 or allowed the magnetometer 50 to continue measuring (e.g., reset a timer), the processor 30 may disable the magnetometer 50. To disable the magnetometer 50, the processor 30 may cause the magnetometer 50 not to provide indications of measurements taken by the magnetometer, or may cause the magnetometer 50 to turn off or enter a low-power state such that the magnetometer 50 does not take magnetic field measurements. The processor 30 may not deactivate the magnetometer 50 if a further trigger condition occurs before the threshold time is reached. The processor 30 may deactivate the magnetometer, regardless of when a most-recent trigger condition occurred, e.g., in response to a power budget being reached or in response to sufficient measurements being provided for determining the calibration factors. An amount of energy used to determine the at least one bias of the magnetometer 50 may be limited. The amount of energy may be limited to a threshold percentage of the energy stored by the battery 35 (and thus the energy used to determine the at least one bias may be limited to different amounts based on the amount of energy presently stored by the battery 35).

Other Considerations

Other examples and implementations are within the scope and spirit of the disclosure and appended claims. For example, due to the nature of software and computers, functions described above can be implemented using software executed by a processor, hardware, firmware, hardwiring, or a combination of any of these. Features implementing functions may also be physically located at various positions, including being distributed such that portions of functions are implemented at different physical locations. For example, one or more features discussed as being performed by the processor 30 may be performed by the magnetometer 50, e.g., by a processor in the magnetometer 50.

Also, as used herein, “or” as used in a list of items prefaced by “at least one of” or prefaced by “one or more of” indicates a disjunctive list such that, for example, a list of “at least one of A, B, or C,” or a list of “one or more of A, B, or C” means A or B or C or AB or AC or BC or ABC (i.e., A and B and C), or combinations with more than one feature (e.g., AA, AAB, ABBC, etc.).

Substantial variations may be made in accordance with specific requirements. For example, customized hardware might also be used, and/or particular elements might be implemented in hardware, software (including portable software, such as applets, etc.) executed by a processor, or both. Further, connection to other computing devices such as network input/output devices may be employed.

The systems and devices discussed above are examples. Various configurations may omit, substitute, or add various procedures or components as appropriate. For instance, features described with respect to certain configurations may be combined in various other configurations. Different aspects and elements of the configurations may be combined in a similar manner. Also, technology evolves and, thus, many of the elements are examples and do not limit the scope of the disclosure or claims.

A wireless communication system is one in which communications are conveyed wirelessly, i.e., by electromagnetic and/or acoustic waves propagating through atmospheric space rather than through a wire or other physical connection. A wireless communication network may not have all communications transmitted wirelessly, but is configured to have at least some communications transmitted wirelessly. Further, the term “wireless communication device,” or similar term, does not require that the functionality of the device is exclusively, or evenly primarily, for communication, or that the device be a mobile device, but indicates that the device includes wireless communication capability (one-way or two-way), e.g., includes at least one radio (each radio being part of a transmitter, receiver, or transceiver) for wireless communication.

Specific details are given in the description to provide a thorough understanding of example configurations (including implementations). However, configurations may be practiced without these specific details. For example, well-known circuits, processes, algorithms, structures, and techniques have been shown without unnecessary detail in order to avoid obscuring the configurations. This description provides example configurations only, and does not limit the scope, applicability, or configurations of the claims. Rather, the preceding description of the configurations provides a description for implementing described techniques. Various changes may be made in the function and arrangement of elements without departing from the spirit or scope of the disclosure.

The terms “processor-readable medium,” “machine-readable medium,” and “computer-readable medium,” as used herein, refer to any medium that participates in providing data that causes a machine to operate in a specific fashion. Using a computing platform, various computer-readable media might be involved in providing instructions/code to processor(s) for execution and/or might be used to store and/or carry such instructions/code (e.g., as signals). In many implementations, a computer-readable medium is a physical and/or tangible storage medium. Such a medium may take many forms, including but not limited to, non-volatile media and volatile media. Non-volatile media include, for example, optical and/or magnetic disks. Volatile media include, without limitation, dynamic memory.

Having described several example configurations, various modifications, alternative constructions, and equivalents may be used without departing from the spirit of the disclosure. For example, the above elements may be components of a larger system, wherein other rules may take precedence over or otherwise modify the application of the invention. Also, a number of operations may be undertaken before, during, or after the above elements are considered. Accordingly, the above description does not bound the scope of the claims.

A statement that a value exceeds (or is more than or above) a first threshold value is equivalent to a statement that the value meets or exceeds a second threshold value that is slightly greater than the first threshold value, e.g., the second threshold value being one value higher than the first threshold value in the resolution of a computing system. A statement that a value is less than (or is within or below) a first threshold value is equivalent to a statement that the value is less than or equal to a second threshold value that is slightly lower than the first threshold value, e.g., the second threshold value being one value lower than the first threshold value in the resolution of a computing system.

1. A mobile device comprising:
a magnetometer configured to sense a magnetic field and to provide indications of the magnetic field; and
a processor communicatively coupled to the magnetometer and configured to:
determine an occurrence of a trigger condition associated with imminent motion of the mobile device, present motion of the mobile device, or decalibration of the magnetometer;
respond to determining the occurrence of the trigger condition by causing the magnetometer to sense the magnetic field and to provide the indications of the magnetic field; and
determine at least one bias of the magnetometer using the indications of the magnetic field.

2. The mobile device of claim 1, wherein to determine the occurrence of the trigger condition, the processor is configured to determine that:
the mobile device received an incoming phone call request; or
the mobile device received an outgoing phone call request; or
a phone call between the mobile device and another device is terminated; or
the mobile device received an incoming message; or
the mobile device sent an outgoing message; or
the mobile device produced a visual notice, an audio notice, or an audiovisual notice; or
a biometric sensor of the mobile device received input from a user; or
the mobile device changed orientation with respect to a direction of gravity; or
a magnetic cable has been detached from the mobile device; or
a camera of the mobile device is activated; or
the camera of the mobile device is deactivated; or
facial recognition of the mobile device is activated; or
a combination of two or more of these.

3. The mobile device of claim 1, wherein the processor is configured to cause the magnetometer to stop providing the indications of the magnetic field in response to a power budget for the magnetometer being reached.

4. The mobile device of claim 1, wherein the processor is configured to disable the magnetometer in response to a threshold amount of time passing after the occurrence of the trigger condition without an occurrence of another trigger condition.

5. The mobile device of claim 1, wherein the processor is configured to compensate for the at least one bias when analyzing further indications of magnetic field from the magnetometer to determine an orientation of the mobile device.

6. The mobile device of claim 1, wherein the magnetometer is configured to provide the indications of the magnetic field as indications of magnetic field intensity in each of three orthogonal directions, and the processor is configured to determine the at least one bias as a distance bias in each of the three orthogonal directions.

7. The mobile device of claim 1, wherein the processor is configured to limit an amount of energy used to determine the at least one bias of the magnetometer.

8. The mobile device of claim 7, wherein the processor is configured to limit the amount of energy used to determine the at least one bias of the magnetometer to a threshold percentage of an amount of energy stored by a battery of the mobile device.

9. A method of obtaining and processing readings of a magnetometer of a mobile device, the method comprising:
determining an occurrence of a trigger condition associated with imminent motion of the mobile device, present motion of the mobile device, or decalibration of the magnetometer;
causing, in response to determining the occurrence of the trigger condition, the magnetometer to sense a magnetic field and to provide indications of the magnetic field; and
determining at least one bias of the magnetometer using the indications of the magnetic field.

10. The method of claim 9, wherein determining the occurrence of the trigger condition comprises determining that:
the mobile device received an incoming phone call request; or
the mobile device received an outgoing phone call request; or
a phone call between the mobile device and another device is terminated; or
the mobile device received an incoming message; or
the mobile device sent an outgoing message; or
the mobile device produced a visual notice, an audio notice, or an audiovisual notice; or
a biometric sensor of the mobile device received input from a user; or
the mobile device changed orientation with respect to a direction of gravity; or
a magnetic cable has been detached from the mobile device; or
a camera of the mobile device is activated; or
the camera of the mobile device is deactivated; or
facial recognition of the mobile device is activated; or
a combination of two or more of these.

11. The method of claim 9, further comprising causing the magnetometer to stop providing the indications of the magnetic field in response to a power budget for the magnetometer being reached.

12. The method of claim 9, further comprising disabling the magnetometer in response to a threshold amount of time passing after the occurrence of the trigger condition without an occurrence of another trigger condition.

13. The method of claim 9, further comprising using the at least one bias to analyze further indications of magnetic field from the magnetometer to determine an orientation of the mobile device.

14. The method of claim 9, wherein the indications comprise indications of magnetic field intensity in each of three orthogonal directions, and wherein each of the at least one bias is a respective distance bias in a respective one of the three orthogonal directions.

15. The method of claim 9, further comprising limiting an amount of energy used to determine the at least one bias of the magnetometer.

16. A mobile device comprising:
means for sensing a magnetic field and providing indications of the magnetic field;
means for determining an occurrence of a trigger condition associated with imminent motion of the mobile device, present motion of the mobile device, or decalibration of the means for sensing the magnetic field;
means for causing, in response to the occurrence of the trigger condition, the means for sensing to sense the magnetic field and to provide the indications of the magnetic field; and
means for determining at least one bias of the means for sensing using the indications of the magnetic field.

17. The mobile device of claim 16, wherein the means for determining the occurrence of the trigger condition are for determining that:
the mobile device received an incoming phone call request; or
the mobile device received an outgoing phone call request; or
a phone call between the mobile device and another device is terminated; or
the mobile device received an incoming message; or
the mobile device sent an outgoing message; or
the mobile device produced a visual notice, an audio notice, or an audiovisual notice; or
a biometric sensor of the mobile device received input from a user; or
the mobile device changed orientation with respect to a direction of gravity; or
a magnetic cable has been detached from the mobile device; or
a camera of the mobile device is activated; or
the camera of the mobile device is deactivated; or
facial recognition of the mobile device is activated; or
a combination of two or more of these.

18. The mobile device of claim 16, further comprising means for causing the means for sensing to stop providing the indications of the magnetic field in response to a power budget for the means for sensing being reached.

19. The mobile device of claim 16, further comprising means for disabling the means for sensing in response to a threshold amount of time passing after the occurrence of the trigger condition without an occurrence of another trigger condition.

20. The mobile device of claim 16, further comprising means for analyzing further indications of magnetic field from the means for sensing to determine an orientation of the mobile device using the at least one bias.

21. The mobile device of claim 16, wherein the indications comprise indications of magnetic field intensity in each of three orthogonal directions, and wherein each of the at least one bias is a respective distance bias in a respective one of the three orthogonal directions.

22. The mobile device of claim 16, wherein the means for determining the at least one bias of the means for sensing comprising limiting means for limiting an amount of energy used to determine the at least one bias of the means for sensing.

23. The mobile device of claim 22, wherein the limiting means are for limiting the amount of energy used to determine the at least one bias of the magnetometer to a threshold percentage of an amount of energy stored by a battery of the mobile device.

24. A non-transitory, processor-readable storage medium comprising processor-readable instructions to cause a processor to:
determine an occurrence of a trigger condition associated with imminent motion of a mobile device, present motion of the mobile device, or decalibration of a magnetometer of the mobile device;
cause, in response to determining the occurrence of the trigger condition, the magnetometer to sense a magnetic field and to provide indications of the magnetic field; and
determine at least one bias of the magnetometer using the indications of the magnetic field.

25. The storage medium of claim 24, wherein the instructions to cause the processor to determine the occurrence of the trigger condition comprises instructions to cause the processor to determine that:
the mobile device received an incoming phone call request; or
the mobile device received an outgoing phone call request; or
a phone call between the mobile device and another device is terminated; or
the mobile device received an incoming message; or
the mobile device sent an outgoing message; or
the mobile device produced a visual notice, an audio notice, or an audiovisual notice; or
a biometric sensor of the mobile device received input from a user; or
the mobile device changed orientation with respect to a direction of gravity; or
a magnetic cable has been detached from the mobile device; or
a camera of the mobile device is activated; or
the camera of the mobile device is deactivated; or
facial recognition of the mobile device is activated; or
a combination of two or more of these.

26. The storage medium of claim 24, further comprising instructions configured to cause the processor to cause the magnetometer to stop providing the indications of the magnetic field in response to a power budget for the magnetometer being reached.

27. The storage medium of claim 24, further comprising instructions configured to cause the processor to disable the magnetometer in response to a threshold amount of time passing after the occurrence of the trigger condition without an occurrence of another trigger condition.

28. The storage medium of claim 24, further comprising instructions configured to cause the processor to determine an orientation of the mobile device using the at least one bias and further indications of magnetic field from the magnetometer.

29. The storage medium of claim 24, wherein the indications comprise indications of magnetic field intensity in each of three orthogonal directions, and wherein each of the at least one bias is a respective distance bias in a respective one of the three orthogonal directions.

30. The storage medium of claim 24, further comprising instructions configured to cause the processor to limit an amount of energy used to determine the at least one bias of the magnetometer.
